(19) United States
(12) Patent Application Publication
(10) Pub. No.: US 2006/0020413 A1
(43) Pub. Date: Jan. 26, 2006

(54) Methods and apparatus for providing automated test equipment with a means to jump and return in a test program

(76) Inventor: Daven Walt Septon, Loveland, CO (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/899,759

(22) Filed: Jul. 26, 2004

(51) Int. Cl. G01R 31/00

(52) U.S. Cl. 702/119

(57) ABSTRACT

Sequences of instructions stored on machine-readable media cause a machine to execute one or more ordered sequences of tests and control functions in a test program, with execution of the tests causing stimuli to be applied to an electrical device under test. Upon execution of a control function that specifies a GOTO, the instructions redirect test program flow to a target of the GOTO (with the target not immediately following the GOTO in test program order). Upon execution of a control function that specifies a RETURN, the instructions cause test program flow to be redirected to an element of the test program that sequentially follows the GOTO. Methods using a GOTO to jump between different sequences of tests, and methods for returning without a RETURN element, are also disclosed.

### BACKGROUND

Prior to manufacture and distribution, electrical devices must be tested to ensure that they perform as intended. One way to test electrical devices such as integrated circuits and system-on-a-chip devices is via automated test equipment (ATE). Although ATE is a great tool, it must be provided with a test program for each device that it is to test. Often, these test programs comprise thousands or even millions of tests that must be sequentially executed to ensure that various structures and functions of a device are adequately tested. The development of such a test program is an arduous task. Furthermore, the storage and memory requirements for handling such a program can be significant.

### SUMMARY OF THE INVENTION

In one embodiment, a number of machine-readable media have stored thereon sequences of instructions that, when executed by a machine, cause the machine to perform the following actions: 1) execute one or more ordered sequences of tests and control functions in a test program (with execution of the tests causing stimuli to be applied to an electrical device under test), 2) upon execution of a control function that specifies a GOTO function, redirect test program flow to a target of the GOTO function (with the target of the GOTO function not immediately following the GOTO function in test program order), and 3) upon execution of a control function that specifies a RETURN, redirect test program flow to an element of the test program that sequentially follows the GOTO.

In one embodiment, a number of machine-readable media have stored thereon sequences of instructions that, when executed by a machine, cause the machine to perform the following actions: 1) execute one or more ordered sequences of tests and control functions in a test program (with execution of the tests causing stimuli to be applied to an electrical device under test), 2) upon execution of a control function that specifies a GOTO function, redirect test program flow to a target of the GOTO function (with the GOTO and target being members of two different sequences of tests), and 3) upon completing execution of a sequence of tests and control functions in which the target of the GOTO resides, redirecting test program flow to an element of the test program that sequentially follows the GOTO.

In another embodiment, a graphical test program editor comprises a window to graphically display a test program comprising one or more ordered sequences of tests and control functions. The sequence order is conveyed by graphical connections between the tests and control functions. The test program editor also comprises a user-selectable GOTO control function that a user may graphically place and connect within the test program, and a user-selectable RETURN control function that a user may graphically place and connect within the test program

Other embodiments are also disclosed.

### BRIEF DESCRIPTION OF THE DRAWINGS

Illustrative and presently preferred embodiments of the invention are illustrated in the drawings, in which:

FIG. 1 illustrates exemplary automated test equipment (ATE);

FIG. 2 illustrates a first exemplary test program;

FIG. 3 illustrates an exemplary test program, wherein the test program comprises an IF/THEN control function;

FIGS. 4 & 5 illustrate exemplary test programs comprising GOTO control functions;

FIGS. 6 & 7 illustrate the use of a GOTO control function in a subsidiary testflow, wherein the GOTO function provides a return to a point other than a default return point in a calling tesfflow;

FIG. 8 illustrates a GOTO control function that jumps to a LABEL element;

FIGS. 9 & 10 illustrate the use of a GOTO control function to repeatedly call a subroutine of tests;

FIG. 11 illustrates an alternate embodiment of the FIG. 10 test program, without the use of a RETURN element;

FIG. 12 illustrates a primary sequence of tests that calls various subroutines of tests;

FIGS. 13-15 illustrate actions that may be performed by a machine during execution of one of the previously illustrated test programs comprising a GOTO function;

FIG. 16 illustrates a graphical test program editor via which a GOTO function may be inserted into a test program;

FIG. 17 illustrates a jump to a GOTO function's corresponding LABEL element within the FIG. 16 test program editor; and

FIG. 18 illustrates an interface of the FIG. 16 editor for turning a placed GOTO function “on” or “off”.

### DETAILED DESCRIPTION OF AN EMBODIMENT

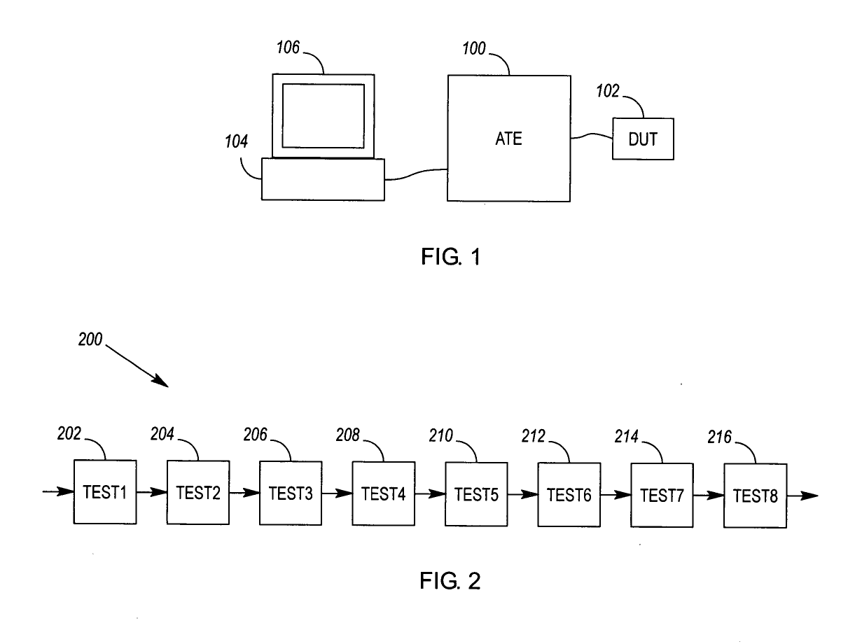

FIG. 1 illustrates exemplary automated test equipment (ATE 100) for testing an electrical device under test (DUT 102). By way of example, the DUT 102 could be an integrated circuit (i.e., an IC, either packaged or in wafer form) or a system-on-a-chip (SOC). The ATE 100 tests the DUT 102 by executing a number of tests which cause electrical stimuli to be applied to the DUT 102. During test, the ATE 100 collects responses to the stimuli (i.e., test results), and evaluates the responses to determine whether the DUT 102 has passed or failed its testing. If the DUT 102 has failed, the ATE 100 can sometimes indicate 1) which test caused the DUT 102 to fail, or 2) what part of the DUT 102 caused the DUT to fail.

In some embodiments, the ATE 100 may be connected to (or comprise) a computer system 104 having a display 106. In this manner, a user may interact with the ATE 100 while developing tests for, or executing tests on, the DUT 102. Alternately, a user may develop tests for the DUT 102 using software running on a computer system that is not connected to the ATE 100.

One exemplary embodiment of ATE 100 is the Agilent 93000™ SOC Series tester provided by Agilent Technologies, Inc. of Palo Alto, Calif., U.S.A.

Typically, ATE 100 will test a DUT 102 under the control of a test program comprising one or more ordered sequences of tests and control functions. Each test may cause a single stimulus, a plurality of stimuli, or a pattern of stimuli to be applied to the DUT 102. By way of example, tests may control and/or measure the following aspects of a DUT: voltages, currents, resistances, capacitances, inductances, frequency responses, jitter, and data inputs and outputs (I/O).

The control functions of the test program may initiate various “setups” prior to the execution of a test, or they may dictate the flow of a test program. For example, one type of control function is the IF/THEN function, wherein program flow is redirected if a given condition has been met. Other types of control functions include FOR loops and WHILE loops.

Often, a test program will comprise thousands or even millions of tests. The development, debug and maintenance of a test program that appropriately and adequately tests a DUT 102 is therefore a time-consuming task that may involve days, weeks or even months of a test developer's time.

FIG. 2 illustrates a first exemplary test program 200 comprised of a sequence of tests (i.e., Test1-Test8). By way of example, the tests of the test program 200 may be contained in a plurality of nodes 202-216 in a linked list, with each node element being uniquely addressable, and with each node element pointing to a next node in the list. Alternately, tests and control functions may be maintained by one or more list structures, each of which can only be entered at its head (e.g., Test1 in FIG. 2).

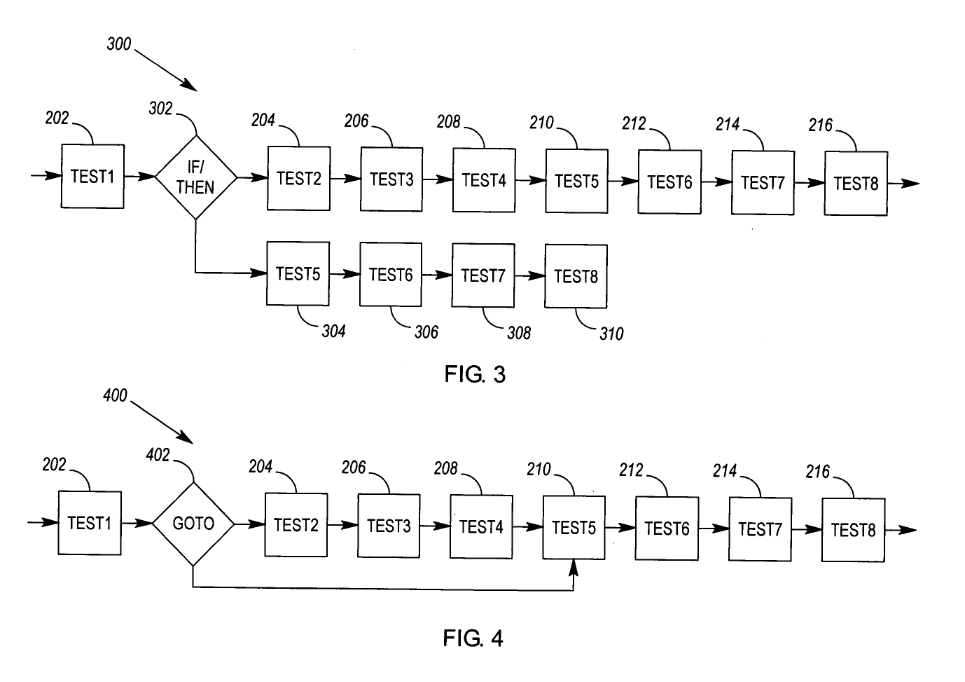

FIG. 3 illustrates a second exemplary test program 300. This second test program 300 comprises an IF/THEN control function 302 following Test1. If the condition(s) specified by the control function are met, the sequence of tests 204-216 beginning with Test2 204 is executed. Otherwise, the sequence of tests 304-310 beginning with Test5 304 is executed. Note that Test5-Test8 are replicated in each of the two alternative branches 204-216, 304-310 of the test program 300. Yet, they are the same tests (with the exception that the contexts in which they are executed may cause them to be executed with different inputs or under different conditions).

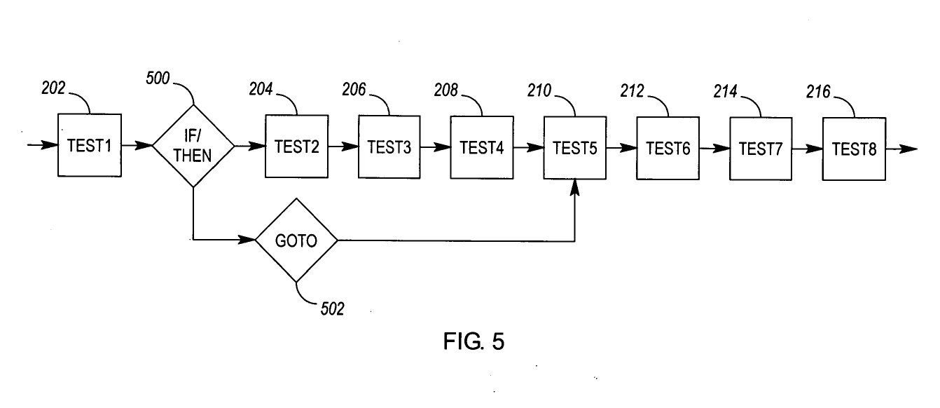

FIG. 4 illustrates a third exemplary test program 400, wherein the IF/THEN control function 302 of the test program 300 has been replaced with a GOTO control function 402. Note that the GOTO control function 402 eliminates the duplicated instances of Test5-Test8 found in test program 300.

Given that sequences of tests in an actual test program can be quite long, and the same tests must often be repeated under different conditions, the GOTO function 402 shown in FIG. 4 can significantly reduce the number of discrete tests that need be included in a test program. In some cases, this can significantly reduce the storage and memory requirements of the test program. Use of a GOTO function 402 can also reduce the effort that is needed to debug and maintain a test program. For example, consider a need to edit Test5 in each of the test programs 300, 400 shown in FIGS. 3 & 4. In the test program 400, Test5 need only be edited in one place. However, in the test program 300, Test5 will likely need to be edited in two places. If Test5 is repeated in additional IF/THEN branches of the test program 300, the difficulty of consistently editing Test5 merely increases. In a large test program comprising thousands or even millions of tests, there comes a point where a test developer can no longer track all of the separate instances of a common test. At this point, the test developer can debug only those instances of a test they can find, with additional instances causing failures (and requiring additional debug efforts) at a later time. Further, if failures of some tests occur at the design stage, while failures of other tests occur during device manufacture, different people may be required to debug different instances of the same tests, and each may do so in different ways, thereby leading to a lack of consistency in a test program. The GOTO control function 402 can therefore be very useful.

The GOTO function 402 presumes that some sort of conditional analysis is built into it. In some cases, it may be desirable to separate these functions, as shown in FIG. 5. By separating the IF/THEN and GOTO functions 500, 502, a test developer or debugger may choose to implement an unconditional GOTO. This can be especially useful during test debug, when it is desired to narrow the possible cause of a problem down to a selected subset of tests. In such a case, an engineer could simply insert a GOTO function that jumps over tests that they do not want to execute.

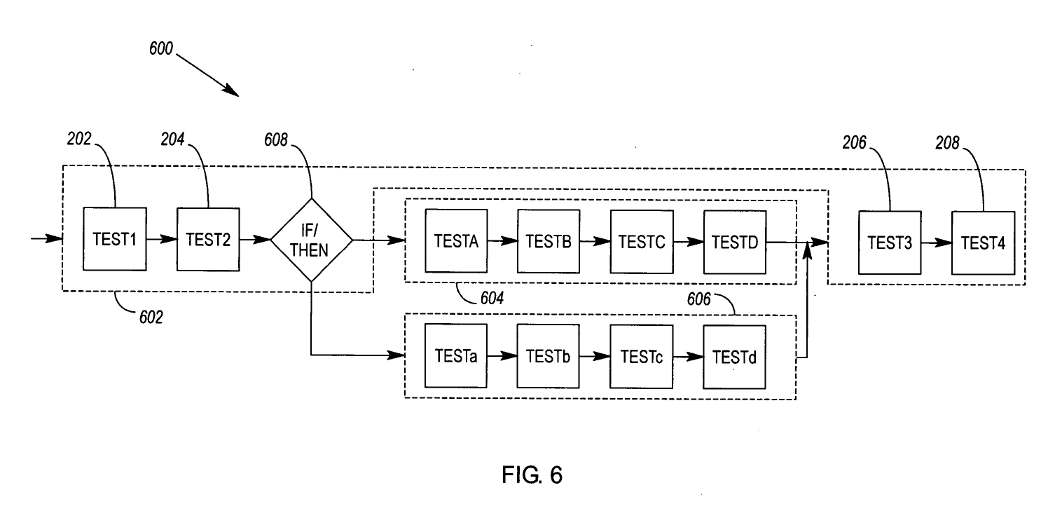

FIGS. 6 & 7 illustrate another use for a GOTO function. FIG. 6 illustrates a test program 600 comprised of three testflows 602, 604, 606. A testflow, as defined herein, is merely a commonly managed set of tests and control functions. Testflows are useful in some cases in that they provide a means of dividing a test program into more easily manageable chunks. By way of example, the Agilent 93000™ SOC Series tester is one example of ATE that processes test programs comprised of testflows. During execution of a testflow 602, a control function such as an IF/THEN function 608 may cause one tesfflow to call another testflow. The subsidiary testflow (e.g., testflow 604 or 606) may then execute a control function (not shown) that causes yet another testflow to be called, such that testflows are called in a nested manner. Upon execution of a calling function (e.g., IF/THEN 608), an identifier of the calling testflow 602 will typically be pushed onto a stack. Then, after the subsidiary testflow (e.g., testflow 606, and any additional testflows that it calls) has completed execution, program flow will return to the calling testflow 602, and the sequence of tests and control functions specified by the calling testflow 602 will finish execution.

One limitation of executing a program comprised of testflows is that, after execution of a subsidiary testflow 606, program flow returns to the calling point in the calling testflow 602. However, there are times when it would be preferable not to return to the calling point. For example, an engineer may realize during debug of the test program 600 that it would be best not to execute Test3 following Testd. In the past, this problem might have been solved by moving Test3 from the calling testflow 602 to the subsidiary testflow 604. However, if Test3 were buried in the middle of a much larger testflow, or if it was desired to move a large number of tests from a calling tesfflow to a subsidiary testflow, this solution might quickly become unwieldy. FIG. 7 therefore illustrates an alternative solution to the problem, wherein a GOTO function 700 is merely inserted at the end of the subsidiary tesfflow 606. Thus, a GOTO “jump” is made to Test4 of the calling tesfflow 602 prior to a conventional “return” to Test3 of testflow 602. Note that jumping between testflows 602-606 may, however, require the deletion of one or more entries from the return stack maintained for “call” returns.

Although the figures illustrate various forward jumps that may be triggered by a GOTO function, the jumping initiated by a GOTO element is not so limited, and backward jumps can also be implemented. In other words, jumping to a target that precedes a GOTO function in test program order is permitted.

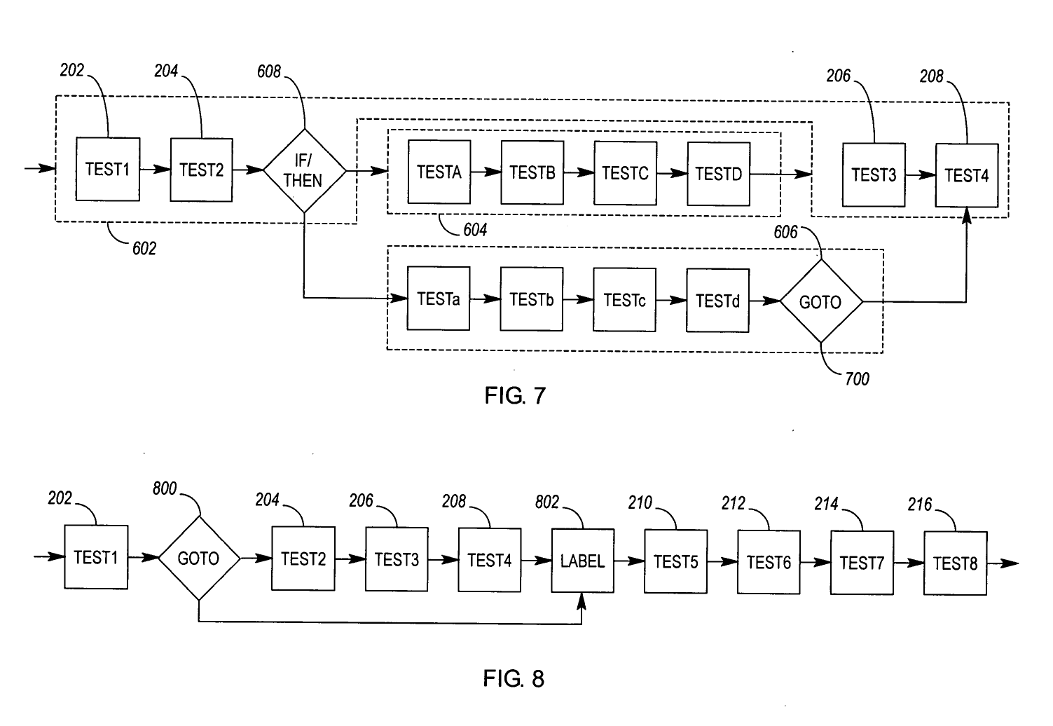

In some cases, the target of a GOTO function may be a test or other control function. However, to clearly delineate the bounds of a GOTO element, it may be desirable to implement a GOTO 800 that jumps to a LABEL element 802. See FIG. 8. Each LABEL element in a test program can then be associated with an identifier (or identifiers) of the “GOTO(s)” of which it is a target. In this manner, accidental deletion of a test or other control function does not leave a GOTO without a target. A label manager implemented in program code may be used to ensure that all labels are identified uniquely.

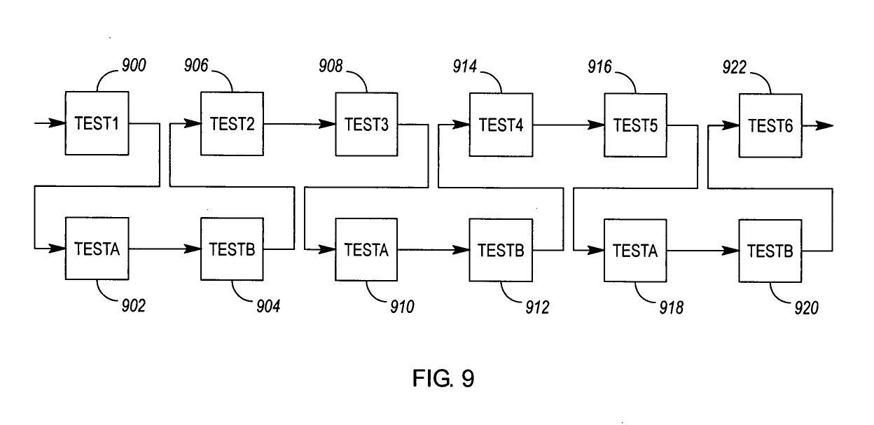

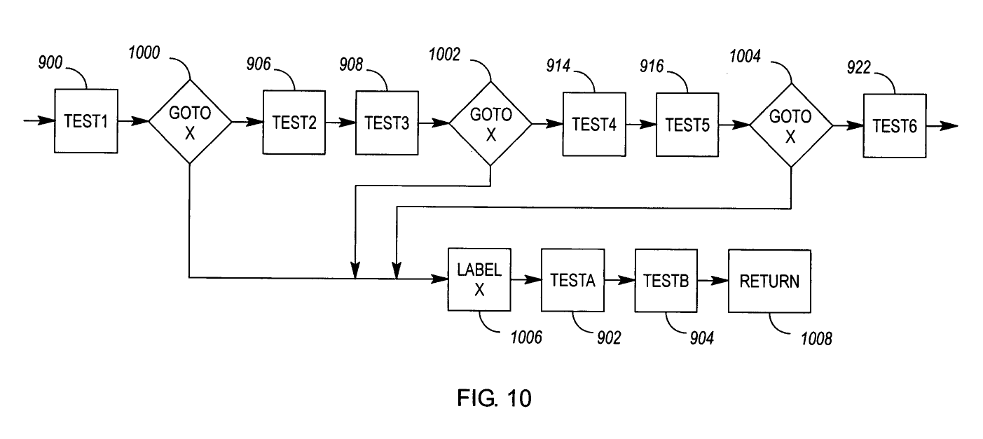

FIGS. 9 & 10 illustrate the use of a GOTO control function to repeatedly call a subroutine of tests. As shown in FIG. 9, one way to repeatedly execute a sequence of tests (e.g., TestA and Test B) is to repeatedly insert the tests (e.g., 902/904, 910/912, 918/920) in a test program 900-922. However, repeating tests within a test program increases the storage requirements of the test program, and can make it difficult to understand and debug. FIG. 10 therefore shows how TestA 902 and TestB 904 can be placed in a subroutine of tests, with the subroutine of tests being repeatedly called via a number of GOTO control functions 1000, 1002, 1004 in a primary test sequence 900, 906, 908, 914, 916, 922. Each time the subroutine of tests 902, 904 is called, an identifier of the calling GOTO function is logged by, for example, pushing it onto a stack or passing it to a RETURN control function 1008. Upon execution of the RETURN element 1008, test program flow is then redirected to an element of the test program that sequentially follows the GOTO function that called the subroutine 902, 904. As shown in FIG. 10, the subroutine of tests 902, 904 may be preceded by a LABEL element 1006.

Although FIG. 10 shows a GOTO function 1000 and its target 1006 to be located within different ordered sequences of a test program (e.g., different testflows), they could alternately be located in the same sequence (or tesfflow).

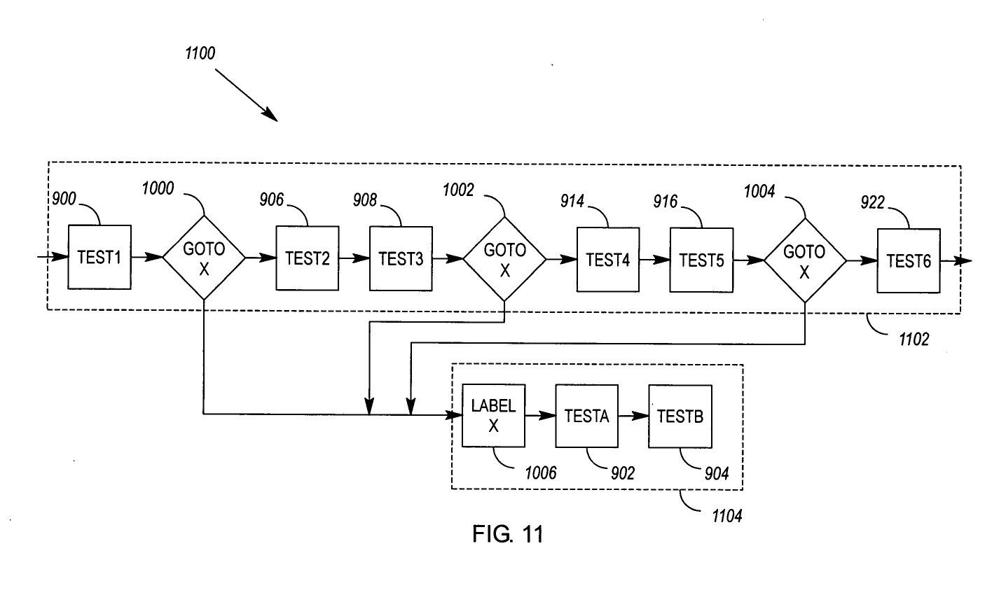

FIG. 11 illustrates an alternate embodiment of the FIG. 10 test program. The FIG. 11 embodiment is similar to the FIG. 10 embodiment, without the use of the RETURN element 1008. In FIG. 11, upon completing execution of the subroutine 902, 904, test program flow is automatically redirected to an element of the test program 1100 that sequentially follows the GOTO function that called the subroutine 902, 904. In one embodiment, such automatic redirection of test program flow may be accomplished by 1) executing tests 900, 906, 908, 914, 916 and 922 in a first tesfflow 1102, 2) executing tests 902 and 904 in a second tesfflow 1104, and 3) executing all tests and control functions in a WHILE loop. Then, upon execution of all of the tests and control functions in the second testflow 1104, the next element executed will, by default, be the element following the GOTO function that called the second testflow 1104.

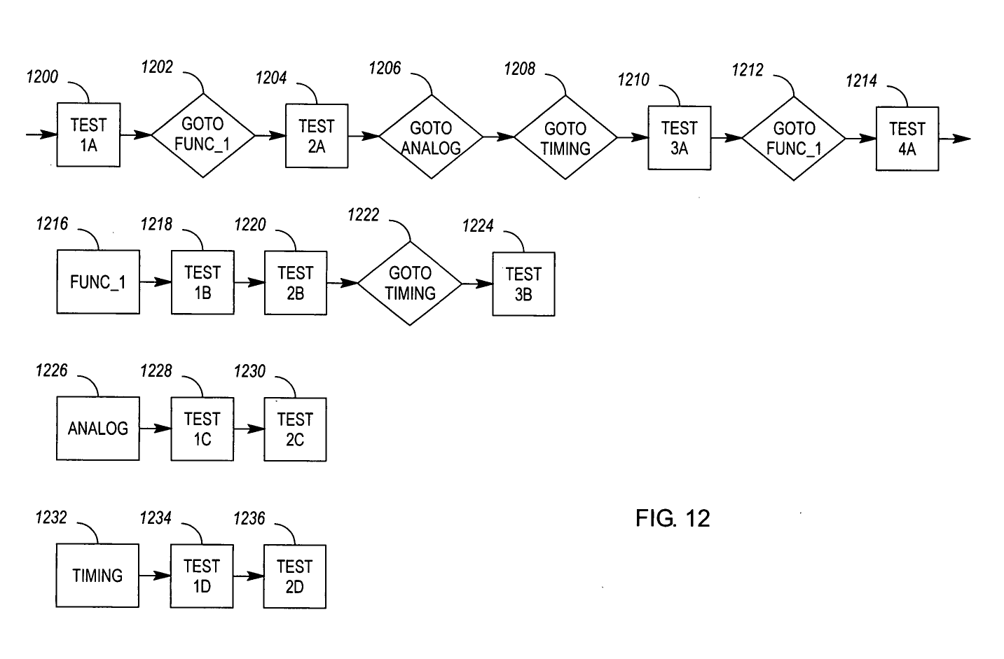

FIG. 12 illustrates how a primary sequence of tests and control functions 1200-1214 may be used to call various subroutines of tests (e.g., subroutines FUNC_1 1216-1224, ANALOG 1226-1230, and TIMING 1232-1236). Note that subroutine FUNC_1 further calls another of the subroutines (i.e., TIMING).

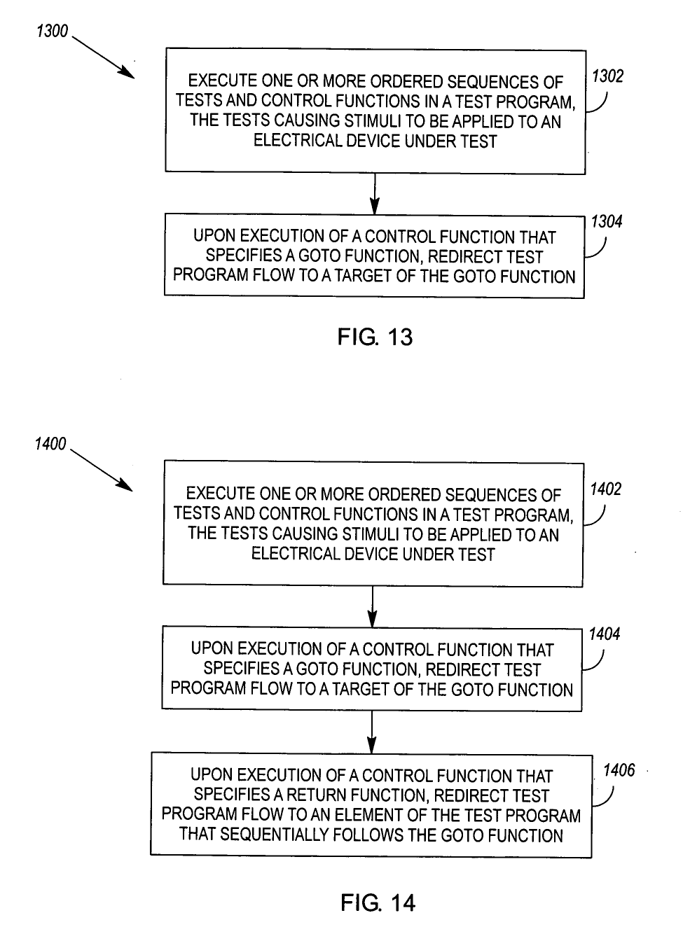

Any of the afore-mentioned test programs comprising a GOTO function may be stored on a number of machine-readable media such as memory (e.g., RAM) or a disk (e.g., a fixed disk such as a hard drive, or a removable disk such a CD-ROM). The same or additional machine-readable media may also store sequences of instructions (e.g., program code) that, when executed by a machine (e.g., ATE 100), cause the machine to perform the actions illustrated in FIG. 13. The actions comprise: executing 1302 one or more ordered sequences of tests and control functions in the test program, the tests causing stimuli to be applied to an electrical DUT 102; and, upon execution of a control function that specifies a GOTO function, redirecting 1304 test program flow to a target of the GOTO function (with the target of the GOTO function not immediately following the GOTO function in test program order).

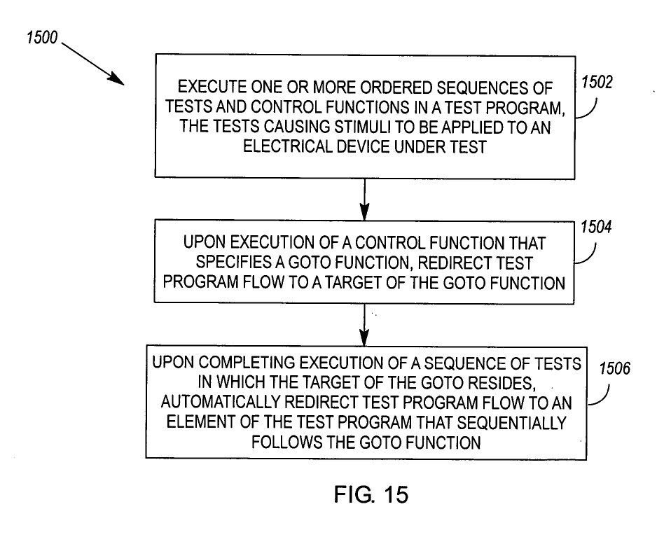

FIGS. 14 and 15 illustrate additional actions that a sequence of instructions stored on machine-readable media may cause a machine to perform. In FIG. 14, the actions comprise: 1) executing 1402 one or more ordered sequences of tests and control functions in the test program, the tests causing stimuli to be applied to an electrical DUT 102; 2) upon execution of a control function that specifies a GOTO function, redirecting 1404 test program flow to a target of the GOTO function (with the target of the GOTO function not immediately following the GOTO function in test program order); and 3) upon execution of a control function that specifies a RETURN, redirecting 1406 test program flow to an element of the test program that sequentially follows the GOTO. In FIG. 15, the actions comprise: 1) executing 1502 one or more ordered sequences of tests and control functions in the test program, the tests causing stimuli to be applied to an electrical DUT 102; 2) upon execution of a control function that specifies a GOTO function, redirecting 1504 test program flow to a target of the GOTO function (with the GOTO and its target being members of two different ordered sequences of tests); and 3) upon completing execution of a sequence of tests and control functions in which said target of the GOTO resides, redirecting 1506 test program flow to an element of the test program that sequentially follows the GOTO.

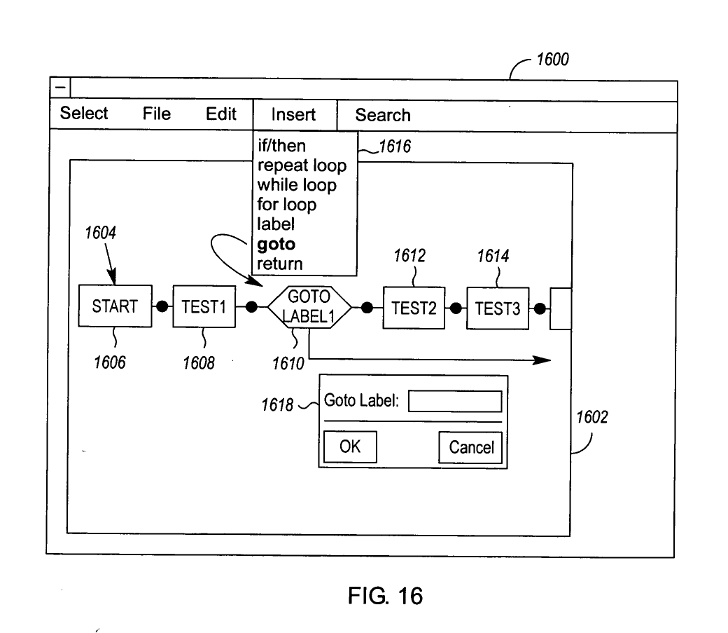

FIG. 16 illustrates a graphical test program editor 1600 via which a GOTO function may be inserted into a test program 1604. In general, the editor 1600 comprises a window 1602 to graphically display a test program 1604 comprising one or more ordered sequences of tests 1608, 1612, 1614 and control functions 1606,1610, and a user-selectable GOTO control function 1610 that a user may graphically place and connect within the test program 1604. Note that the sequence order of the test program 1604 is conveyed by graphical connections (e.g., connecting lines) between, and order of, the tests 1608, 1612, 1614 and control functions 1606, 1610. By way of example, the GOTO function 1610 may be selected from a drop-down menu 1616 or iconic toolbar of the editor 1600.

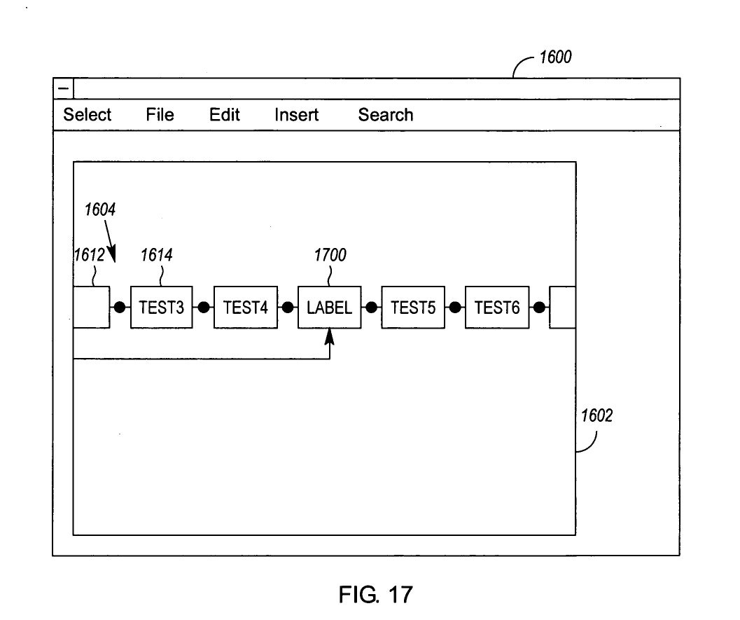

In one embodiment, the editor 1600 further comprises 1) a user-selectable LABEL element 1700 (FIG. 17) that a user may graphically place and connect within the test program 1604, and 2) an interface 1618 to define connections between placed ones of the GOTO control functions and LABEL elements. The editor 1600 may also comprise a user-selectable RETURN control function that a user may graphically place and connect within the test program 1604.

To assist in defining the connections between GOTO functions 1610 and LABEL elements 1700, the editor 1600 may further comprise an interface for naming GOTO functions 1610 and LABEL elements 1700. This interface may take the form of dialog boxes that are launched by selecting (e.g., right-clicking on) ones of the GOTO functions 1610 or LABEL elements 1700.

The test program editor 1600 may further associate GOTO commands with the placed GOTO functions. In one embodiment, a GOTO command is executed as a result of 1) selecting one of the placed GOTOs, and then 2) selecting the GOTO command (e.g., from a pop-up menu launched by right-clicking on the GOTO). Execution of the GOTO command causes the test program window 1602 to update its display to show at least the target 1700 of the selected GOTO 1610 (see FIG. 17).

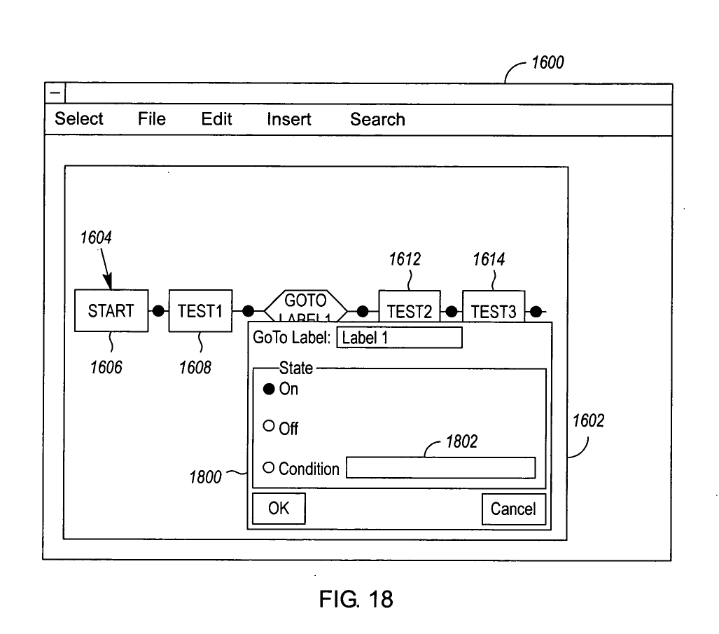

The test program editor 1600 may further comprise an interface 1800 for turning placed GOTO functions “on” and “off” (see FIG. 18). The “on” and “off” statuses may then be used to determine whether the GOTO functions will be executed during execution of the edited test program 1604. In one embodiment, the interface 1800 for turning the GOTO functions “on” and “off” further accepts user-defined conditions 1802. These conditions may then be assessed during execution of the edited test program 1604 to determine whether GOTO functions should be executed. This can be especially useful in debugging a test program (e.g., by using GOTO functions to skip tests and thereby isolate a problem).

Preferably, placed GOTO control functions are graphically connected to their GOTO targets (whether they be label elements, tests, nodes or other control functions). In one embodiment, these graphical connections are displayed in different manners, depending on different statuses associated with the placed GOTO control functions. For example, if a GOTO function is “on”, a connection between a GOTO function and its LABEL element may be designated by a solid or green line. If the GOTO function is turned “off”, its connection with its LABEL element may be deleted, shown with a dashed line, or shown in a red color.

As discussed in part above, GOTO control functions can be variously used to eliminate duplicated tests within a test program, to bypass tests during debug, to jump to tests out of sequence, to reduce test program bulk, and to make test programs easier to understand.

What is claimed is:

1. A number of machine-readable media having stored thereon sequences of instructions that, when executed by a machine, cause the machine to perform the actions of:
executing one or more ordered sequences of tests and control functions in a test program, the execution of said tests causing stimuli to be applied to an electrical device under test;
upon execution of a control function that specifies a GOTO, redirecting test program flow to a target of the GOTO, said target not immediately following said GOTO in test program order; and
upon execution of a control function that specifies a RETURN, redirecting test program flow to an element of the test program that sequentially follows said GOTO.

2. The machine-readable media of claim 1, wherein the target of the GOTO is a label within the test program.

3. The machine-readable media of claim 1, wherein the GOTO and target of the GOTO are located within different ordered sequences of said test program.

4. The machine-readable media of claim 1, wherein the test program comprises a plurality of linked nodes containing said tests and control functions.

5. The machine-readable media of claim 1, wherein each of said ordered sequences of tests and control functions is contained within a corresponding list structure.

6. A number of machine-readable media having stored thereon sequences of instructions that, when executed by a machine, cause the machine to perform the actions of:
executing one or more ordered sequences of tests and control functions in a test program, the execution of said tests causing stimuli to be applied to an electrical device under test;
upon execution of a control function that specifies a GOTO, redirecting test program flow to a target of the GOTO, said GOTO and target being members of two different ordered sequences of tests; and
upon completing execution of a sequence of tests in which said target of the GOTO resides, automatically redirecting test program flow to an element of the test program that sequentially follows said GOTO.

7. The machine-readable media of claim 6, wherein the GOTO and its target respectively reside in first and second testflows.

8. The machine-readable media of claim 7, wherein the second testflow contains a RETURN, the machine-readable media further comprising instructions that, upon execution of the RETURN, cause said redirection of test program flow to said element of the test program sequentially following said GOTO.

9. The machine-readable media of claim 7, wherein:
said instructions execute all testflows in a WHILE loop and; and
upon the second tesfflow completing execution, the WHILE loop causes said redirection of test program flow to said element of the test program sequentially following said GOTO.

10. The machine-readable media of claim 6, wherein the target of the GOTO is a label within the test program.

11. A graphical test program editor, comprising:
a window to graphically display a test program comprising one or more ordered sequences of tests and control functions, said sequence order being conveyed by graphical connections between the tests and control functions;
a user-selectable GOTO control function that a user may graphically place and connect within said test program; and
a user-selectable RETURN control function that a user may graphically place and connect within said test program.

12. The graphical test program editor of claim 11, further comprising:
a user-selectable label element that a user may graphically place and connect within said test program; and
an interface to define connections between placed ones of said GOTO control functions and label elements.

13. The graphical test program editor of claim 12, further comprising an interface for naming said placed ones of said GOTO control functions and label elements.

14. The graphical test program editor of claim 13, wherein said interface for naming said placed ones of said GOTO control functions and label elements comprises dialog boxes that are launched by selecting ones of the GOTO control functions or label elements.
